(19) United States
(12) Patent Application Publication
(10) Pub. No.: US 2015/0263184 A1
(43) Pub. Date: Sep. 17, 2015

(54) PHOTOCOUPLER

(71) Applicant: Kabushiki Kaisha Toshiba, Tokyo (JP)

(72) Inventors: Naoya Takai, Yukuhashi Fukuoka (JP); Yoichiro Ito, Nakatsu Oita (JP)

(21) Appl. No.: 14/476,488

(22) Filed: Sep. 3, 2014

(30) Foreign Application Priority Data
Mar. 14, 2014 (JP) 2014-052666
Aug. 29, 2014 (JP) 2014-175832

(51) Int. Cl. H01L 31/02; H01L 23/64; H01L 31/0304; H01L 31/167; H01L 25/16

(52) U.S. Cl. CPC H01L 31/02002; H01L 31/167; H01L 25/167; H01L 25/165; H01L 31/03046; H01L 23/645; H01L 29/78

(57) ABSTRACT

A photocoupler includes: an insulating substrate; an input terminal; an output terminal; a die pad part; a light emitting element; and a light receiving element. The insulating substrate includes a first layer and a second layer. The insulating substrate is provided with a plurality of through holes. The input terminal includes a first terminal and a second terminal. The first terminal includes a first conductive region, a second conductive region, a through conductive region, and a first spiral conductive region. The second terminal includes a first conductive region, a second conductive region, a through conductive region, and a second spiral conductive region. The light receiving element is bonded to the die pad part and connected to the output terminal. The light emitting element is bonded to an upper surface of the light receiving element.

### CROSS-REFERENCE TO RELATED APPLICATIONS

This application is based upon and claims the benefit of priority from Japanese Patent Application No. 2014-052666, filed on Mar. 14, 2014, and No. 2014-175832, filed on Aug. 29, 2014; the entire contents of which are incorporated herein by reference.

### FIELD

Embodiments described herein relate generally a photocoupler.

### BACKGROUND

Photocouplers including photorelays can convert an input electrical signal to an optical signal using a light emitting element, receive the optical signal by a light receiving element, and then output an electrical signal. Thus, the photocoupler can transmit an electrical signal in the state in which the input and the output are insulated from each other.

In electronic equipment such as semiconductor testers, different power supply systems such as the DC voltage system, AC voltage system, telephone line system, and control system are often placed in one device. However, direct coupling between different power supply systems and circuit systems may cause malfunctions.

Use of a photocoupler provides insulation between different power supplies. This can suppress malfunctions.

For instance, a semiconductor tester includes numerous photocouplers for DC loads and AC loads. Furthermore, the mounting circuit board in the semiconductor tester is populated with e.g. filters for cutting extraneous radio frequency noise and external resistors for driving light emitting elements with a prescribed driving voltage supplied from MCU (microcontroller unit) or the like. Such filters and external resistors are connected to the respective photocouplers. This increases the size of the mounting circuit board. Thus, the electronic equipment such as a semiconductor tester is enlarged.

### BRIEF DESCRIPTION OF THE DRAWINGS

FIG. 1A is a schematic sectional view of a photocoupler according to a first embodiment, FIG. 1B is a schematic plan view of a mounting substrate in which a conductive pattern is provided in an insulating substrate;

FIG. 2 is an equivalent circuit diagram of the photocoupler according to the first embodiment;

FIG. 3A is a configuration view of an application example of the photocoupler, FIG. 3B is a waveform diagram of the input current to the light emitting element, and FIG. 3C is a waveform diagram of the drain current of the MOSFET;

FIG. 4 shows an equivalent circuit of a photocoupler according to a comparative example;

FIG. 5A is a schematic sectional view of a photocoupler according to a second embodiment, FIG. 5B is a schematic plan view of a mounting substrate in which a conductive pattern is provided in an insulating substrate;

FIG. 6 is an equivalent circuit diagram of the photocoupler according to the second embodiment;

FIG. 7A is a schematic perspective view of a photocoupler according to a third embodiment, FIG. 7B is a schematic sectional view thereof, and FIG. 7C is a schematic plan view before molding the sealing resin layer;

FIG. 8 is a configuration view of a driving circuit of the photocoupler of this embodiment;

FIG. 9 is a configuration view of an application example of the photocoupler according to the comparative example;

FIG. 10 is a schematic view illustrating a variation of the photocoupler of the third embodiment;

FIG. 11 is a schematic plan view of a photocoupler according to a fourth embodiment;

FIGS. 12A-12D are circuit diagrams constituting low pass filters;

FIG. 13 is a graph representing a dependency of transmission loss on frequency according to the fourth embodiment;

FIG. 14 is a circuit diagram explaining an example of the transmission loss measuring circuit; and

FIG. 15 is a graph representing a dependency of transmission loss on frequency according to the comparative example.

### DETAILED DESCRIPTION

In general, according to one embodiment, a photocoupler includes: an insulating substrate; an input terminal; an output terminal; a die pad part; a light emitting element; and a light receiving element. The insulating substrate includes a first layer and a second layer, with a first surface being a lower surface of the first layer and a second surface being an upper surface of the second layer. The insulating substrate is provided with a plurality of through holes. The input terminal includes a first terminal and a second terminal. The first terminal includes a first conductive region provided on the first surface, a second conductive region provided on the second surface, a through conductive region provided inside the plurality of through holes, and a first spiral conductive region provided between the first layer and the second layer and connected to the first conductive region and the second conductive region via the through conductive region. The second terminal includes a first conductive region provided on the first surface, a second conductive region provided on the second surface, a through conductive region provided inside the plurality of through holes, and a second spiral conductive region provided between the first layer and the second layer and connected to the first conductive region and the second conductive region via the through conductive region. The die pad part is provided between the input terminal and the output terminal on the second surface. The light receiving element is bonded to the die pad part and connected to the output terminal. The light emitting element is bonded to an upper surface of the light receiving element and includes a first electrode connected to the second conductive region of the first terminal and a second electrode connected to the second conductive region of the second terminal.

Embodiments of the invention will now be described with reference to the drawings.

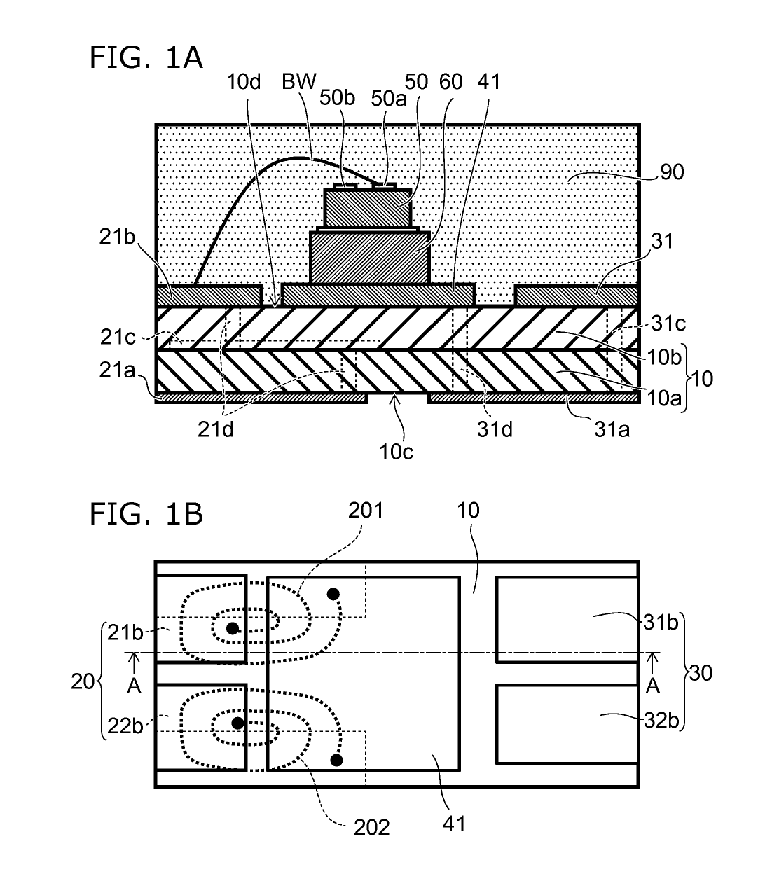

FIG. 1A is a schematic sectional view of a photocoupler according to a first embodiment. FIG. 1B is a schematic plan view of a mounting substrate in which a conductive pattern is provided in an insulating substrate.

The photocoupler includes an insulating substrate 10, an input terminal 20, an output terminal 30, a (first) die pad part 41, a light receiving element 60, and a light emitting element 50.

FIG. 1A is a schematic sectional view taken along line A-A of FIG. 1B. The insulating substrate 10 includes a first layer 10a and a second layer 10b. The lower surface of the first layer 10a constitutes a first surface 10c. The upper surface of the second layer 10b constitutes a second surface 10d. The insulating substrate 10 is provided with a plurality of through holes.

The input terminal 20 includes a first terminal 21 and a second terminal 22. The first terminal 21 includes a first conductive region 21a provided on the first surface 10c, a second conductive region 21b provided on the second surface 10d, a through conductive region 21d provided inside the plurality of through holes, and a first spiral conductive region 201 provided between the first layer 10a and the second layer 10b and connected to the first conductive region 21a and the second conductive region 21b via the through conductive region 21d.

The second terminal 22 includes a first conductive region 22a provided on the first surface 10c, a second conductive region 22b provided on the second surface 10d, a through conductive region provided inside the plurality of through holes, and a second spiral conductive region 202 provided between the first layer and the second layer and connected to the first conductive region 22a and the second conductive region 22b via the through conductive region. The first conductive region of the input terminal 20 and the first conductive region of the output terminal 30 constitute surface mounted electrodes.

The die pad part 41 is sandwiched between the input terminal 20 and the output terminal 30 and provided on the second surface 10d.

The light receiving element 60 is bonded to the die pad part 41 and connected to the output terminal 30. The light receiving element 60 can be e.g. a photodiode or a light receiving IC.

The light emitting element 50 is bonded to the upper surface of the light receiving element 60. The light emitting element 50 includes a first electrode 50a and a second electrode 50b. The first electrode 50a is connected to the second conductive region 21b of the first terminal 21. The second electrode 50b is connected to the second conductive region 22b of the second terminal 22. The light emitting element 50 can be e.g. an LED (light emitting diode) made of e.g. AlGaAs or InAlGaP and being capable of emitting light of a wavelength of 740-850 nm. Here, the light emitting element 50 and the light receiving element 60 can be provided with a bonding layer (not shown) made of e.g. translucent resin.

A sealing resin layer 90 is made of e.g. silicone resin. The sealing resin layer 90 constitutes a protective layer covering the second conductive region of the input terminal 20, the second conductive region of the output terminal 30, the die pad part 41, the second surface 10d, the light receiving element 60, the light emitting element 50, the second surface, the bonding wire BW and the like.

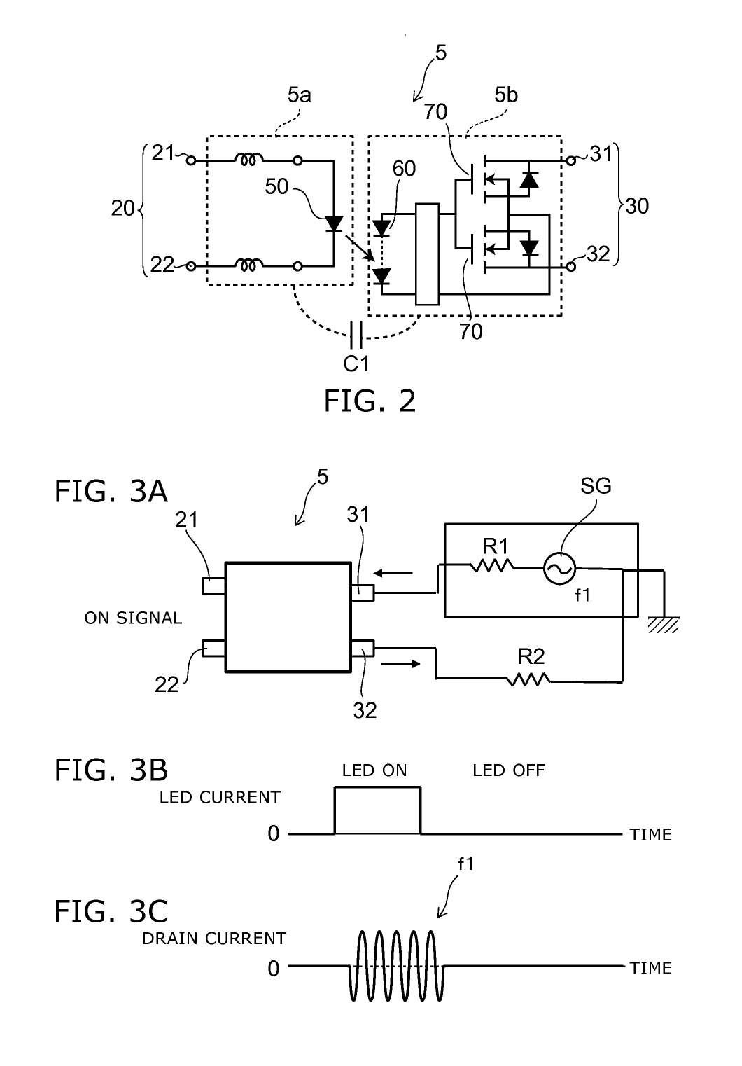

FIG. 2 is an equivalent circuit diagram of the photocoupler according to the first embodiment.

The first spiral conductive region 201 and the second spiral conductive region 202 are configured as e.g. a wiring pattern provided between the first layer 10a and the second layer 10b of the insulating substrate 10. In this figure, the first spiral conductive region 201 and the second spiral conductive region 202 do not cross each other in plan view.

The length of the first and second spiral conductive regions 201, 202 is made sufficiently larger than the width of the conductive region. Thus, the first and second spiral conductive regions 201, 202 exhibit an inductive reactance (inductance) against radio frequency noise and act as a low-pass filter.

A stray capacitance C1 (or parasitic capacitance) exists via the insulating substrate 10 and the like between the input terminal 20 and the output terminal 30. The stray capacitance C1 is e.g. 0.5 pF.

FIG. 3A is a configuration view of an application example of the photocoupler. FIG. 3B is a waveform diagram of the input current to the light emitting element. FIG. 3C is a waveform diagram of the drain current of the MOSFET.

The photocoupler can control an AC load. The AC signal source SG has e.g. frequency f1 of 1 GHz or more.

As shown in FIG. 3A, the input signal to the light emitting element such as LED is a pulse current. The light emitting element 50 is turned on by the input signal. Next, the MOSFET 70 is turned on by the photovoltaic power of the light receiving element 60. When the polarity of the AC voltage changes, the current path of the MOSFET 70 is switched. During the period when the light emitting element 50 such as LED is turned on, an AC signal is supplied to the load R2. That is, the photocoupler operates as a photorelay.

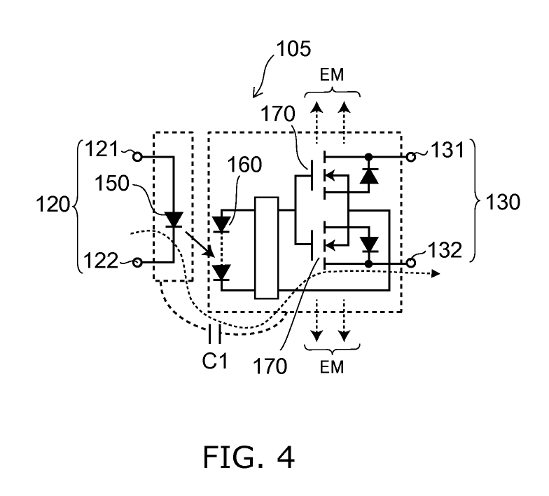

FIG. 4 shows an equivalent circuit of a photocoupler according to a comparative example.

If the frequency f1 of the AC signal source SG is as high as 1 GHz or more, a radio frequency signal externally leaks from the radio frequency current path. In a semiconductor tester in which thousands or more of photocouplers are mounted on the mounting circuit board, the electromagnetic wave EM leaked from the light receiving part 5b of a photocoupler affects the input part 5a of another photocoupler. Furthermore, radio frequency noise due to the electromagnetic wave EM injected from outside also affects the input part 5a.

The radio frequency noise injected into the light emitting part 5a reaches the light receiving part 5b through the stray capacitance C1 of the photocoupler. For instance, if the frequency f1 is 10 GHz, the capacitive reactance of the stray capacitance C1 of 0.5 pF is 31.8Ω. Thus, the noise can reach the output terminal 30. Accordingly, radio frequency noise is superposed on the output signal depending on the intensity of the radio frequency noise and the external load, and may distort the output signal waveform. An external peripheral element such as a low-pass filter can be provided on the input side of each photocoupler to reduce the influence of the radio frequency noise. However, this increases the size of the mounting circuit board.

In the first embodiment, an inductor is incorporated in the insulating substrate 10. Thus, the size of the photocoupler is not increased, and there is no need to provide a low-pass filter on the mounting circuit board. Accordingly, the mounting circuit board can be downsized, and its assembly process can be simplified. As a result, the semiconductor tester including numerous first photocouplers can accurately and rapidly measure e.g. a high-speed DRAM.

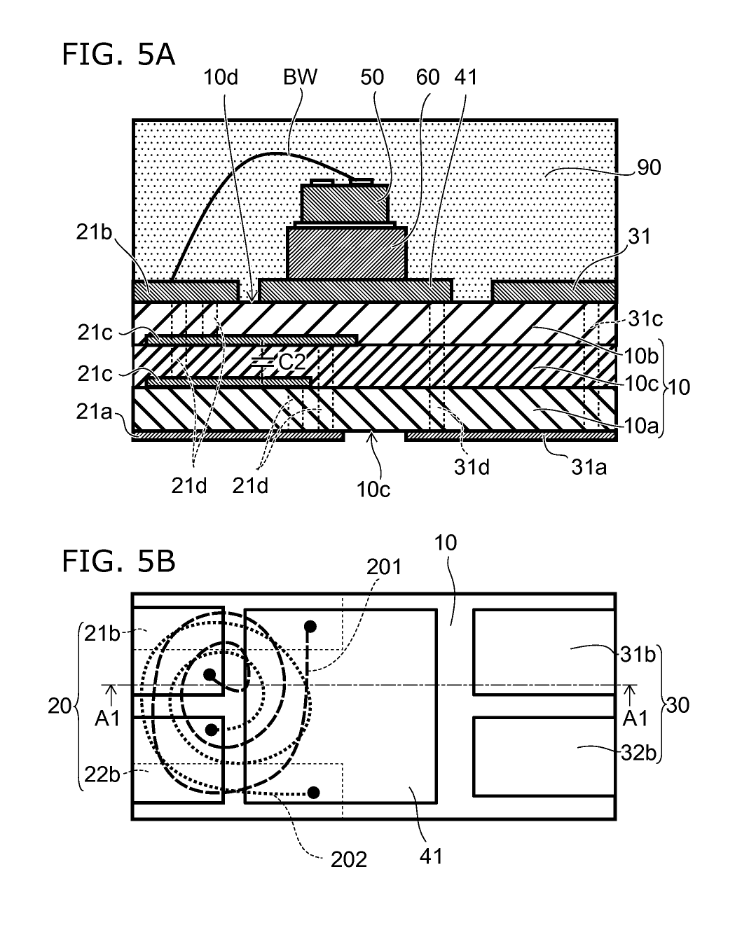

FIG. 5A is a schematic sectional view of a photocoupler according to a second embodiment. FIG. 5B is a schematic plan view of a mounting substrate in which a conductive pattern is provided in an insulating substrate.

The photocoupler includes an insulating substrate 10, an input terminal 20, an output terminal 30, a die pad part 41, a light receiving element 60, and a light emitting element 50.

The insulating substrate 10 includes a first layer 10a, a second layer 10b, and a third layer 10c. The lower surface of the first layer 10a constitutes a first surface 10c. The upper surface of the second layer 10b constitutes a second surface 10d. The insulating substrate 10 is provided with a plurality of through holes.

A first spiral conductive region 201 is provided between the first layer 10a and the third layer 10c and connected to the first conductive region 21a and the second conductive region 21b of the first terminal 21 via the through conductive region.

A second spiral conductive region 202 is provided between the second layer 10b and the third layer 10c and connected to the first conductive region 22a and the second conductive region 22b of the second terminal 22 via the through conductive region. The first spiral conductive region 201 and the second spiral conductive region 202 cross each other in plan view.

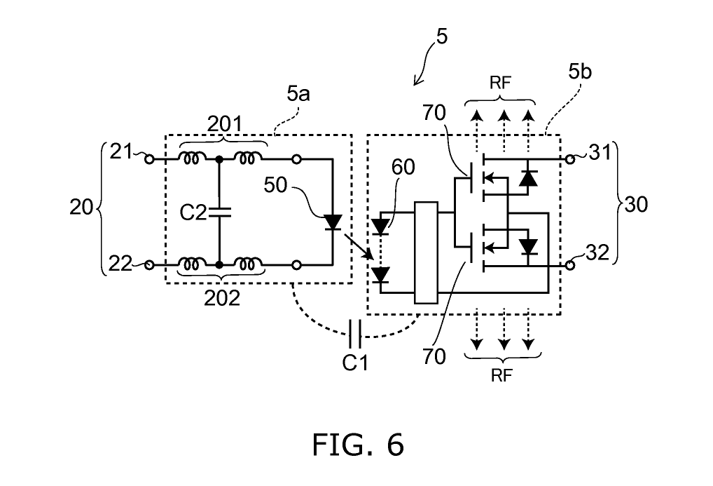

FIG. 6 is an equivalent circuit diagram of the photocoupler according to the second embodiment.

The first spiral conductive region 201 and the second spiral conductive region 202 sandwich the third layer 10c in between and are spatially close to each other. Thus, a stray capacitance C2 occurs between the first spiral conductive region 201 and the second spiral conductive region 202. The stray capacitance C2 can be increased by thinning the third layer 10c. That is, the input terminal 20 can constitute a low-pass (high-cut) filter inside the insulating substrate 10. Therefore, it can be suppressed that high frequency noise from the input terminal 20 leaks in the output terminal 30 via the stray capacitance C1.

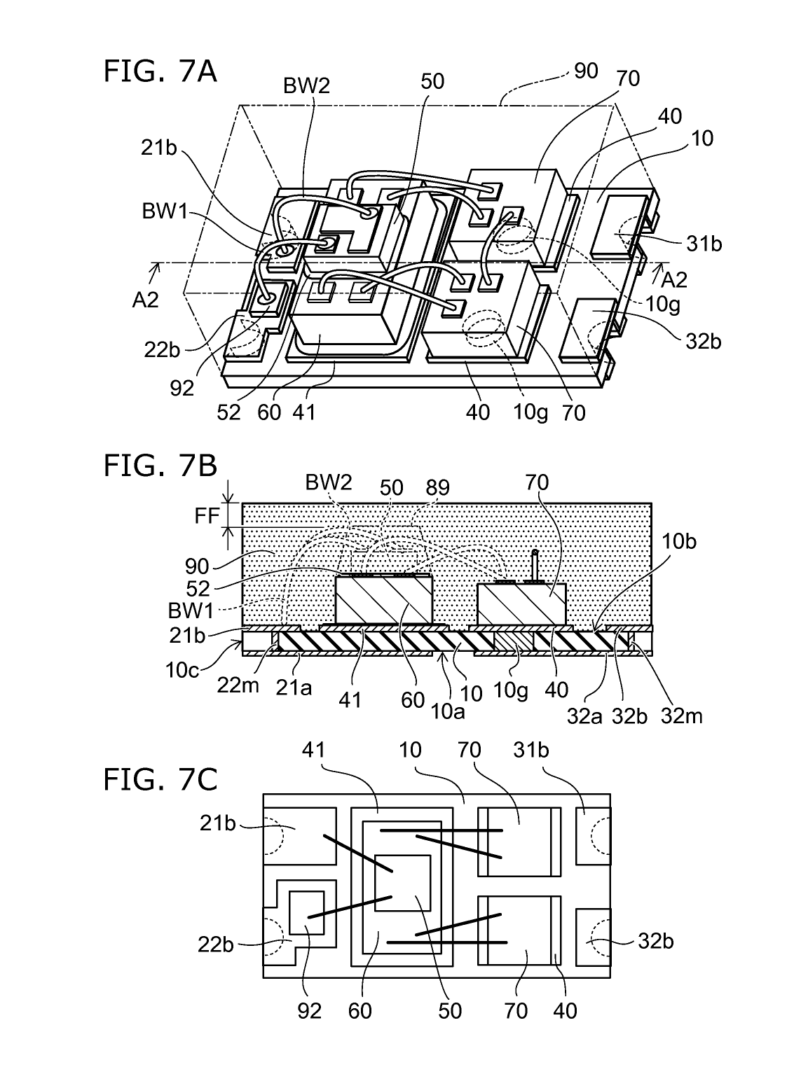

FIG. 7A is a schematic perspective view of a photocoupler according to a third embodiment. FIG. 7B is a schematic sectional view thereof. FIG. 7C is a schematic plan view before molding the sealing resin layer.

The photocoupler includes an insulating substrate 10, an input terminal 20, an output terminal 30, a first die pad part 41, a second die pad part 40, a light receiving element 60, a resistor 92, a light emitting element 50, and a MOSFET 70. FIG. 7B is a schematic sectional view taken along line A2-A2.

The insulating substrate 10 has a first surface 10a and a second surface 10b. The input terminal 20 includes a first terminal 21 and a second terminal 22. The first terminal 21 includes a first conductive region 21a provided on the first surface 10a and a second conductive region 21b provided on the second surface 10b. The second terminal 22 includes a first conductive region 22a provided on the first surface 10a and a second conductive region 22b provided on the second surface 10b.

The output terminal 30 includes a first terminal 31 and a second terminal 32. The first terminal 31 includes a first conductive region 31a provided on the first surface 10a and a second conductive region 31b provided on the second surface 10b. The second terminal 32 includes a first conductive region 32a provided on the first surface 10a and a second conductive region 32b provided on the second surface 10b.

The first die pad part 41 is sandwiched between the input terminal 20 and the output terminal 30 and provided on the second surface 10b. The light receiving element 60 is bonded to the first die pad part 41. The second die pad part 40 is sandwiched between the first die pad part 41 and the output terminal 30 and provided on the second surface 10b.

The resistor 92 is bonded to the second conductive region 21b of the first terminal 21 of the input terminal 20. One terminal (back surface side) of the resistor 90 is connected to the second conductive region 21b. The resistor 92 can be shaped like a chip and configured as a top-bottom electrode structure. The size of the resistor 92 is as small as e.g. 0.3 mm×0.3 mm. The size of the insulating substrate 10 is set to e.g. 2.8 mm×1.4 mm. Thus, the size of the resistor 92 can be made sufficiently small.

The light emitting element 50 is bonded to the upper surface of the light receiving element 60. The light emitting element 50 includes a first electrode 50a and a second electrode 50b. The first electrode 50a of the light emitting element 50 is connected to the other end of the upper surface side of the resistor 92 by e.g. a bonding wire. The second electrode 50b of the light emitting element 50 is connected to the second conductive region 22b of the second terminal 22 by e.g. a bonding wire.

The MOSFET 70 includes a drain connected to the second conductive region of the output terminal 30 and a gate and a source connected to the light receiving element 60. In this figure, the MOSFET 70 includes two elements in source-common connection. This can supply an AC signal including a radio frequency signal to an external load. In the case of no switching control of the AC signal, the number of MOSFETs 70 may be one. Alternatively, the MOSFET may be omitted.

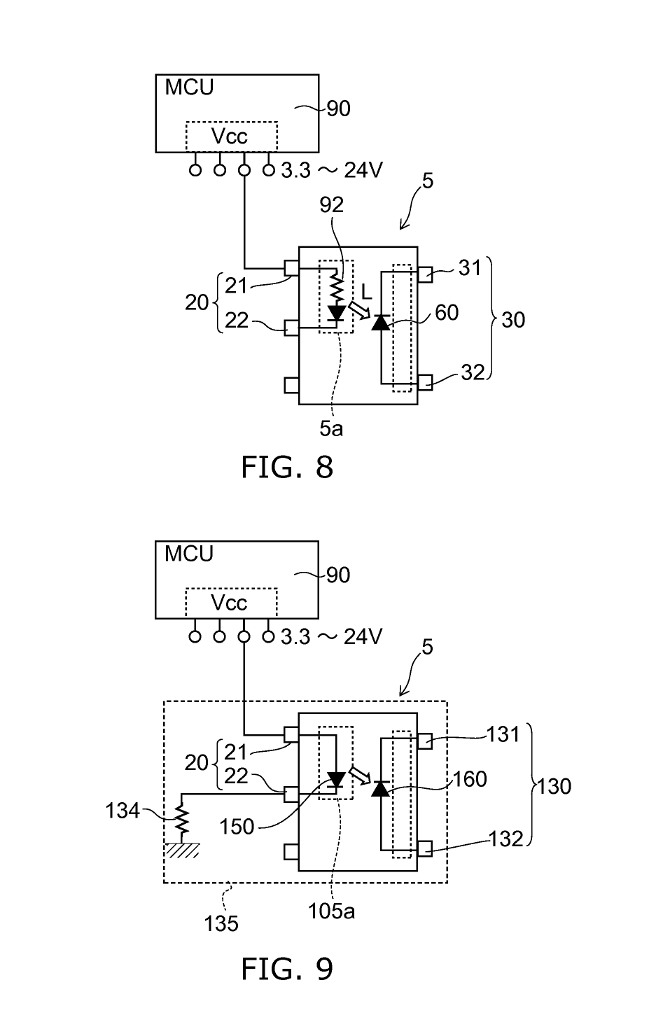

FIG. 8 is a configuration view of a driving circuit of the photocoupler of this embodiment.

The power supply voltage Vcc of the MCU (microcontroller unit) 90 for driving the photocoupler is e.g. 3.3, 5, 12, or 24 V. In the third embodiment, the photocoupler includes the resistor 92. Thus, a prescribed power supply voltage of the MCU 90 can be directly applied to the input terminal 20 of the photocoupler to voltage-drive the light emitting element 50. For instance, the power supply voltage Vcc of the MCU 90 is 12 V, and the trigger current of the photocoupler is 20 mA. If the forward voltage of the light emitting element 50 is 2 V, the value of the resistor 92 can be set to generally 500 Ω.

FIG. 9 is a configuration view of an application example of the photocoupler according to the comparative example.

The light emitting element 150 is series connected to an external resistor 134. For instance, the output voltage of the MCU 90 is 12 V, and the value of the external resistor 134 is 1.3 kΩ. Then, the light emitting element 150 can be driven with the forward current IF set to 8 mA. In this case, a wiring part is provided on the mounting circuit board 135, and the resistor 134 is attached thereto by e.g. soldering. In the case where numerous photocouplers need to be densely arranged as in a semiconductor tester, the presence of externally attached peripheral elements causes the problem of increasing the mounting process steps and enlarging the electronic equipment such as a semiconductor tester.

In contrast, according to the third embodiment, there is no need of external resistors outside the photocoupler. Thus, the photocoupler can be directly driven by the power supply voltage Vcc of the MCU 90. This can downsize the electronic equipment. Furthermore, the characteristics change of the light emitting element 50 with temperature and time is reduced because the light emitting element 50 is voltage-driven.

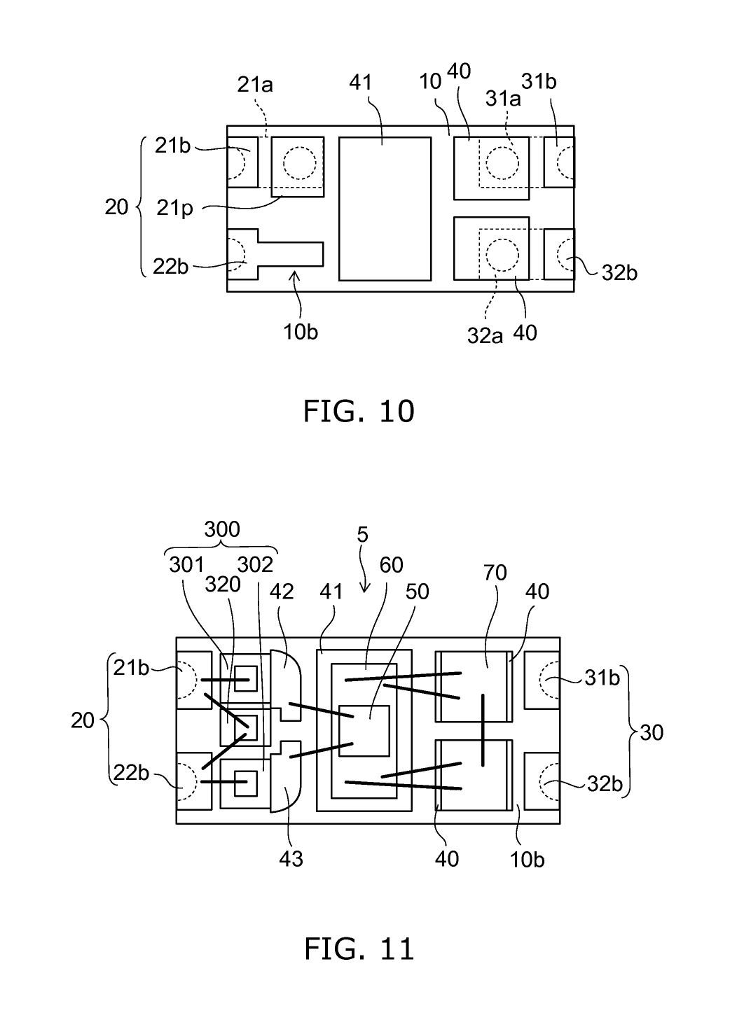

FIG. 10 is a schematic view illustrating a variation of the photocoupler of the third embodiment.

This figure is a schematic plan view showing an insulating substrate 10 used in the variation and a conductive pattern provided thereon. The first terminal 21 of the input terminal 20 further includes a spaced region 21p spaced from the second conductive region 21b on the second surface 10b. The spaced region 21p is connected to the first conductive region 21a provided on the first surface 10a via the conductive region in the through hole TH provided in the insulating substrate 10. The resistor 92 is bonded to the spaced region 21p. The other terminal of the resistor 92 is connected to the first electrode of the light emitting element by e.g. a bonding wire.

Thus, the sealing resin layer covering the resistor, the MOSFET, the light receiving element, and the light emitting element can keep high adhesiveness to the second surface 10b of the insulating substrate 10. If there is a region in which the metallic terminal surface is bonded to the sealing resin layer, moisture may penetrate from the boundary surface therebetween and degrade the resistor and the semiconductor element. The variation facilitates suppressing such degradation to improve the reliability of the photocoupler.

FIG. 11 is a schematic plan view of a photocoupler according to a fourth embodiment.

The sealing layer is omitted in FIG. 11. The photocoupler 5 includes an insulating substrate 10, an input terminal 20, an output terminal 30, a first die pad part 41, a light receiving element 60, and a light emitting element 50, and a low-pass filter 300.

The insulating substrate 10 has a first surface and a second surface 10b. The input terminal 20 has a first terminal 21 and a second terminal 22. The first terminal 21 includes a first conductive region provided on the first surface and a second conductive region 21b provided on the second surface 10b. The second terminal 22 includes a first conductive region provided on the first surface and a second conductive region 22b provided on the second surface 10b.

The output terminal 30 includes a first conductive region provided on the first surface and a second conductive region 31b, 32b provided on the second surface 10b.

The first die pad part 41 is sandwiched between the input terminal 20 and the output terminal 30 on the second surface 21b. The light receiving element 60 is bonded to the first die pad part 41 by the solder (not shown), the conductive adhesive (not shown) and so on, and connected to the output terminal 30. The light emitting element 50 is bonded to the upper surface of the light receiving element 60. The low pass-filter 300 is provided between the input terminal 20 and the light emitting element 50 on the second surface 10b.

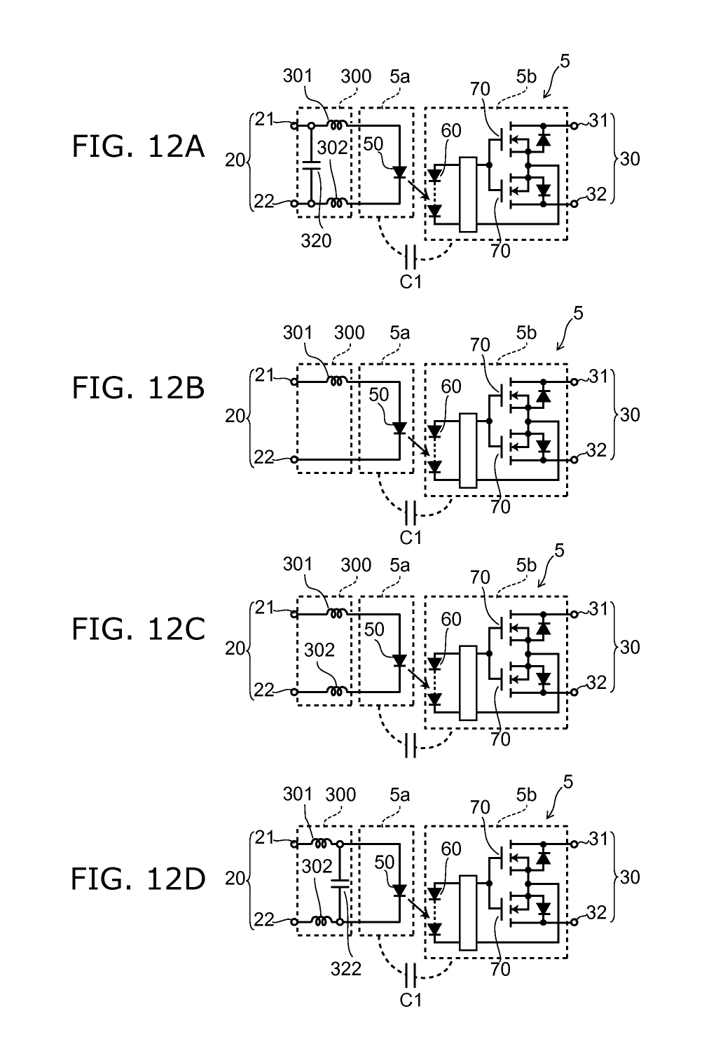

The photocoupler can further have a second die pad part 40 and a MOSFET 70. The second die pad part 40 is sandwiched between the first die pad part 41 and the output terminal 30 on the second surface 10b. The MOSFET 70 has a drain connected to the second conductive region 31b, 32b, a gate connected to the light receiving element 60 and a source connected to the light receiving element 60. The MOSFET 70 includes 2 elements in source-common connection. FIG. 12A shows a circuit diagram of the low-pass filter of the photocoupler in FIG. 11. The low-pass filter 300 includes a first inductor 301 provided between the first terminal 21 and one electrode of the light emitting element 50, and a second inductor 302 provided between the second terminal 22 and the other electrode of the light emitting element 50 and a capacitor 320 connected to the first terminal 21 and the second terminal 22. Here, the first inductor 301 is bonded to a die pad part 42 provided on the second surface 10b, and the second inductor 302 is bonded to a die pad part 43 provided on the second surface 10b.

High frequency signal and high frequency noise arrive at the input terminal 20 from outside, but do not pass through the low pas-filter 300. Therefore, it is suppressed that the high frequency signal and high frequency noise leak in the light receiving part 5b via the stray capacitor C1.

On the other hand, when the frequency of the high frequency source connected to the output terminal 30 becomes high, a part of high frequency signal leak in the light emitting part 5a via the stray capacitance C1. However, it is difficult that the high frequency signal passes though the input terminal 20. Therefore, it is suppressed that the high frequency signal leaks outward from the input terminal 20.

When the inductors 301, 302 are, for example, chip inductors for high frequency application, it is not needed that the low-pass filter 300 is provided on the mounting circuit board. Therefore, size of the mounting circuit board can be shrunk. Also, the chip inductor may be a stacked structure of ceramic material and a coil material, or solenoidal structure having a ceramic core wound with spiral conductive wire.

Furthermore, the inductor 301 may be provided between the first terminal 21 and the one electrode of the light emitting element 50, as shown in FIG. 12B. The inductor may be provided between the second terminal 22 and the other electrode of the light emitting element 50. As shown in FIG. 12D, the capacitor 322 may be provided on a side of the light emitting element 50.

In the photocouplers, the light emitting element 50 is driven in low repetition frequency pulse compared to high frequency signal, as shown in FIG. 3B. That is, the low-pass filter 300 passes the low repetition frequency pulse, but cut off the high frequency signal noise.

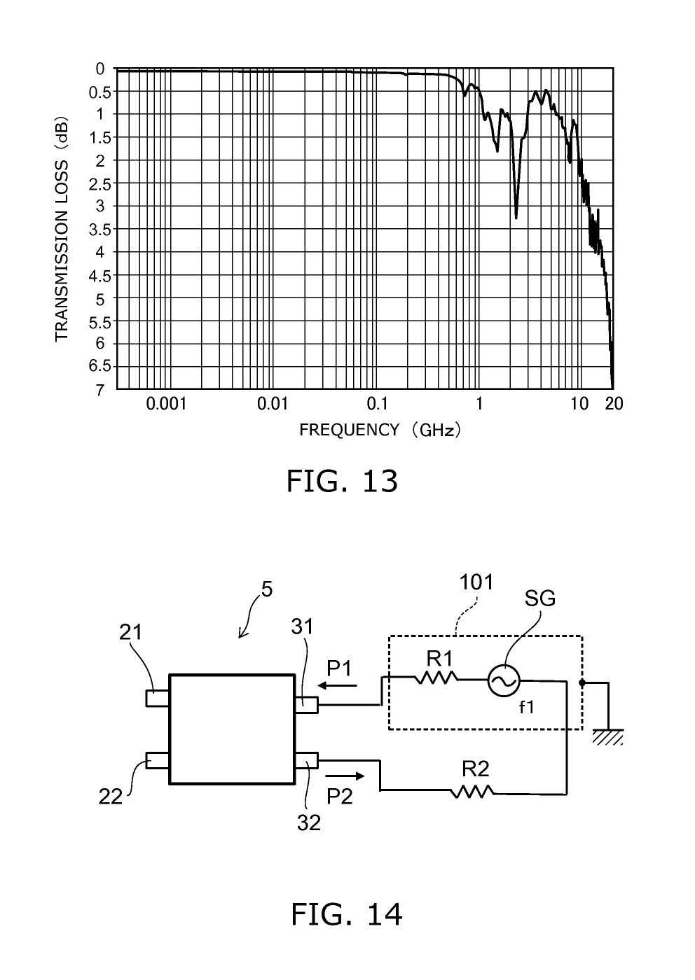

FIG. 13 is a graph representing a dependency of transmission loss on frequency according to the fourth embodiment.

A vertical axis represents a transmission loss (dB), and a horizontal axis represents a frequency (GHz). The transmission loss is as low as 3 dB at 10 GHz. Therefore, it becomes possible to measure a high-speed DRAM quickly and accurately by using high speed pulse having a short rise time and a short fall time.

FIG. 14 is a circuit diagram explaining an example of the transmission loss measuring circuit.

After the light emitting element turns on by the input electrical signal, the MOSFET turns on. Subsequently, the high frequency signal from the high frequency signal source 101 is applied to the load R2. The output terminal 31, 32 of the photocoupler corresponds to the terminals of the mechanical relay. Therefore, the transmission loss of the photocoupler corresponds to the insertion loss in on-state of the relay. The transmission loss TL is represented in the following formula.

TL (dB)=−10 log(P2/P1)

where P1 is an input power and P2 is an output power.

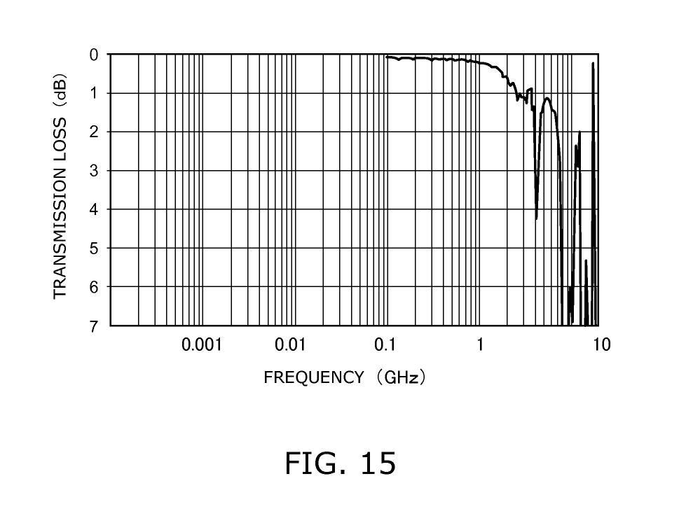

FIG. 15 is a graph representing a dependency of transmission loss on frequency according to the comparative example.

The photocoupler 105 according to the comparative example do not have a low-pass filter, as shown in FIG. 4. As the high frequency signal leaks in an input terminal 120 via the stray capacitance C1 from the output terminal 130, the transmission loss increases by 3 dB near 7 GHz. Therefore, the measuring accuracy becomes lower in the case of pulse operation corresponding to a frequency more than 7 GHz. The first to third embodiments and the variation associated therewith provide a photocoupler including peripheral circuit elements and being capable of reducing the size of the external mounting circuit board. Thus, electronic equipment such as a semiconductor tester is downsized. Furthermore, the assembly process thereof is simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A photocoupler comprising:
an insulating substrate including a first layer and a second layer, with a first surface being a lower surface of the first layer and a second surface being an upper surface of the second layer, the insulating substrate being provided with a plurality of through holes;
an input terminal including a first terminal and a second terminal, the first terminal including a first conductive region provided on the first surface, a second conductive region provided on the second surface, a through conductive region provided inside the plurality of through holes, and a first spiral conductive region provided between the first layer and the second layer and connected to the first conductive region and the second conductive region via the through conductive region, and the second terminal including a first conductive region provided on the first surface, a second conductive region provided on the second surface, a through conductive region provided inside the plurality of through holes, and a second spiral conductive region provided between the first layer and the second layer and connected to the first conductive region and the second conductive region via the through conductive region;
an output terminal;
a die pad part provided between the input terminal and the output terminal on the second surface;
a light receiving element bonded to the die pad part and connected to the output terminal; and
a light emitting element bonded to an upper surface of the light receiving element and including a first electrode connected to the second conductive region of the first terminal and a second electrode connected to the second conductive region of the second terminal.

2. The photocoupler according to claim 1, wherein the first spiral conductive region and the second spiral conductive region do not cross each other in plan view.

3. The photocoupler according to claim 1, wherein
the insulating substrate further includes a third layer between the first layer and the second layer,
the first spiral conductive region is provided between the first layer and the third layer and connected to the first conductive region and the second conductive region of the first terminal via the through conductive region,
the second spiral conductive region is provided between the second layer and the third layer and connected to the first conductive region and the second conductive region of the second terminal via the through conductive region, and
the first spiral conductive region and the second spiral conductive region cross each other in plan view.

4. The photocoupler according to claim 1, wherein the first spiral conductive region and the second spiral conductive region have inductance against radio frequency noise, respectively.

5. The photocoupler according to claim 1, wherein
the light emitting element emits light of a wavelength of 740-850 nm, and
the light receiving element receives the light through the upper surface of the light receiving element.

6. The photocoupler according to claim 1, further comprising:
a MOSFET including a drain connected to the second conductive region of the output terminal, a gate connected to the light receiving element and a source connected to the light receiving element.

7. The photocoupler according to claim 6, wherein the MOSFET includes two elements in source-common connection.

8. A photocoupler comprising:
an insulating substrate having a first surface and a second surface;
an input terminal including a first terminal and a second terminal, the first terminal including a first conductive region provided on the first surface and a second conductive region provided on the second surface, and the second terminal including a first conductive region provided on the first surface and a second conductive region provided on the second surface;
an output terminal including a first conductive region provided on the first surface and a second conductive region provided on the second surface;
a first die pad part provided between the input terminal and the output terminal on the second surface;
a second die pad part provided between the first die pad part and the output terminal on the second surface;
a light receiving element bonded to the first die pad part and connected to the output terminal;
a light emitting element bonded to an upper surface of the light receiving element and including a first electrode and a second electrode;
a resistor provided on the second surface side of the input terminal and connected to the input terminal and the light emitting element; and
a MOSFET including a drain connected to the second conductive region of the output terminal, a gate connected to the light receiving element and a source connected to the light receiving element, and bonded to the second die pad part.

9. The photocoupler according to claim 8, further comprising:
a sealing resin layer provided on the second surface of the insulating substrate so as to seal the light receiving element, the light emitting element, and the MOSFET.

10. The photocoupler according to claim 8, wherein the resistor is bonded to the second conductive region of the first terminal or the second conductive region of the second terminal.

11. The photocoupler according to claim 8, wherein
the output terminal further includes a conductive through region provided in the insulating substrate and connecting the first conductive region and the second conductive region,
the first terminal or the second terminal further includes a conductive through region provided in the insulating substrate and connecting the first conductive region and the second conductive region, and a third conductive region spaced from the second conductive region and provided on the second surface, and
the resistor is bonded to the third conductive region and connected to the input terminal and the light emitting element.

12. The photocoupler according to claim 11, further comprising:
a sealing resin layer provided on the second surface of the insulating substrate so as to seal the light receiving element, the light emitting element, the MOSFET, and the resistor.

13. The photocoupler according to claim 8, wherein the first spiral conductive region and the second spiral conductive region have inductance against radio frequency noise, respectively.

14. The photocoupler according to claim 8, wherein
the light emitting element emits light of a wavelength of 740-850 nm, and
the light receiving element receives the light through the upper surface of the light receiving element.

15. The photocoupler according to claim 8, wherein the MOSFET includes two elements in source-common connection.

16. A photocoupler comprising:
an insulating substrate having a first surface and a second surface;
an input terminal including a first terminal and a second terminal, the first terminal including a first conductive region provided on the first surface and a second conductive region provided on the second surface, and the second terminal including a first conductive region provided on the first surface and a second conductive region provided on the second surface;
an output terminal including a first conductive region provided on the first surface and a second conductive region provided on the second surface;
a first die pad part provided between the input terminal and the output terminal on the second surface;
a light receiving element bonded to the first die pad part and connected to the output terminal;
a light emitting element bonded to an upper surface of the light receiving element; and
a low-pass filter provided between the input terminal and the light emitting element on the second surface.

17. The photocoupler according to claim 16, wherein the low-pass filter includes an inductor.

18. The photocoupler according to claim 17, wherein a capacitor connected to the first terminal of the input terminal and the second terminal of the input terminal.

19. The photocoupler according to claim 16, further comprising:
a second die pad part sandwiched between the first die pad part and the output terminal on the second surface; and
a MOSFET including a drain connected to the second conductive region of the output terminal, a gate connected to the light receiving element and a source connected to the light receiving element, and bonded to the second die pad part.
